(19) United States
(12) Patent Application Publication
(10) Pub. No.: US 2026/0144055 A1
(43) Pub. Date: May 21, 2026

(54) SELF-ALIGNED BUMP-LESS BONDING

(71) Applicant: International Business Machines Corporation, Armonk, NY (US)

(72) Inventors: Reinaldo Vega, Mahopac, NY (US); Nicholas Anthony Lanzillo, Wynantskill, NY (US); James Patrick Mazza, Saratoga Springs, NY (US); Takashi Ando, Eastchester, NY (US); David Wolpert, Poughkeepsie, NY (US); Uzma Rana, Slingerlands, NY (US)

(21) Appl. No.: 18/949,408

(22) Filed: Nov. 15, 2024

(51) Int. Cl. H01L 23/00; H01L 23/522; H01L 25/065

(52) U.S. Cl. CPC H10W 20/497; H10W 72/926; H10W 72/936; H10W 72/9445; H10W 72/952; H10W 90/00; H10W 90/26; H10W 90/792

(57) ABSTRACT

Three dimensional electronic structures are provided in which ferromagnetic elements are present in both a first substrate and a second substrate to provide self-aligned contact of metal wiring that is present in the first substrate and the second substrate.

### BACKGROUND

The present application relates to semiconductor technology, and more particularly to a three-dimensional (3D) electronic structure in which ferromagnetic elements present in both a first substrate and a second substrate are employed to provide self-aligned contact of metal wiring that is present in the first substrate and the second substrate.

With the increasing demand for heterogeneous integration via 3D integration, there is significant interest in reducing interconnect pitch since smaller pitch enables higher density and more efficient circuits that can lead to reduced power consumption and design complexity. In terms of interconnects'scaling roadmap, as solder micro-bumps and solder copper pillars reach their scaling limits, solder-free bump-less interconnect emerge as one viable option for 3D integration. Bump-less interconnect bonding permits higher pitch scaling at a reduced cost to the manufacture as compared to conventional solder bump bonding.

### SUMMARY

3D electronic structures are provided in which ferromagnetic elements are present in both a first substrate and a second substrate to provide self-aligned contact of metal wiring that is present in the first substrate and the second substrate. The first and second substrates can be bonded together without the use of solder bumps.

In one embodiment of the present application, a 3D electronic structure is provided that includes a first substrate including at least one first ferromagnetic element embedded in an outermost portion of the first substrate; and a second substrate including at least one second ferromagnetic element embedded in an outermost portion of the second substrate, in which the at least one first ferromagnetic element is aligned to the at least one second ferromagnetic element at an interface that is present between the first substrate and the second substrate.

In another embodiment of the present application, a 3D electronic structure is provided that includes a first substrate including a first back-end-of-the line (BEOL) structure located on a first front-end-of-the-line (FEOL) level, in which the first BEOL structure includes first metal wiring and at least one first ferromagnetic element located in an outermost portion of the first BEOL structure. The 3D electronic structure of this embodiment further includes a second substrate including a second BEOL structure located on a second FEOL level, in which the second BEOL structure includes second metal wiring and at least one second ferromagnetic element located in an outermost portion of the second BEOL structure. In accordance with the present application, the at least one first ferromagnetic element is aligned to the at least one second ferromagnetic element at an interface that is present between the first substrate and the second substrate, and the first metal wiring is electrically connected to the second metal wiring at the interface.

In yet another embodiment of the present application, a 3D electronic structure is provided that includes a first substrate including a first portion of an inductor coil, a second substrate including a second portion of the inductor coil, in which the second portion of the inductor coil is in direct electrical contact with the first portion of the inductor coil at an interface between the first substrate and the second substrate, and a ferromagnetic core in which the ferromagnetic core is surrounded by the inductor coil.

### BRIEF DESCRIPTION OF THE DRAWINGS

FIG. 1 is cross sectional view of an exemplary 3D electronic structure in accordance with an embodiment of the present application.

FIG. 2 is a cross sectional view of an exemplary 3D electronic structure in accordance with another embodiment of the present application.

FIG. 3 is a cross sectional view of a first exemplary structure that can be used in the present application in providing the exemplary 3D electronic structure shown in FIG. 1, the first exemplary structure including a first BEOL structure located on a FEOL level.

FIG. 4 is a cross sectional view of first exemplary structure shown in FIG. 4 after forming openings into an upper portion of a first interlayer dielectric (ILD) region of the first BEOL structure.

FIG. 5 is a cross sectional view of the first exemplary structure shown in FIG. 4 after forming a first ferromagnetic material containing structure into each of the openings.

FIG. 6 is a cross sectional view of the first exemplary structure shown in FIG. 5 after applying a first global external magnetic field (GMF1) to polarize each first ferromagnetic material containing structure forming first ferromagnetic elements.

FIG. 7 is a cross sectional view of a second exemplary structure including a second BEOL structure located on a second FEOL level, in which a second global external magnetic field (GMF2) is applied to polarize second ferromagnetic material containing structures located in the second ILD layer of the second FEOL structure forming second ferromagnetic elements.

FIG. 8 is a cross sectional view after performing a coarse alignment step at a first distance in which the first exemplary structure illustrated in FIG. 6 is flipped and positioned above the second exemplary structure shown in FIG. 7.

FIG. 9 is a cross sectional view of after performing a fine alignment step at a second distance that is less than the first distance on the coarse-aligned first exemplary structure and second exemplary structure shown in FIG. 8.

FIG. 10 is a cross sectional view of the first exemplary structure shown in FIG. 5 after applying a first semi-local external magnetic field (SLMF1) to alternatively polarize the first ferromagnetic material containing structures forming a pair of oppositely polarized ferromagnetic elements.

FIG. 11 is a cross sectional view of a second exemplary structure including a second BEOL structure located on a second FEOL level, in which a second semi-local external magnetic field (SLMF2) is applied to alternatively polarize the second ferromagnetic material containing structures in the second BEOL structure forming a pair of oppositely polarized ferromagnetic elements.

FIG. 12 is a cross sectional view after performing a coarse alignment step at a first distance in which the first exemplary structure illustrated in FIG. 10 is flipped and positioned above the second exemplary structure shown in FIG. 11.

FIG. 13 is a cross sectional view after performing a fine alignment step at a second distance that is less than the first distance on the coarse-aligned first exemplary structure and second exemplary structure shown in FIG. 12.

FIG. 14A is a cross sectional view of an exemplary first structure that can be employed in providing a 3D electronic structure including an inductor coil surrounding a ferromagnetic core.

FIG. 14B is a top down view of the exemplary first structure illustrated in FIG. 14A.

FIG. 15A is a cross sectional view of an exemplary second structure that can be employed in providing the 3D electronic structure including the inductor coil surrounding the ferromagnetic coil.

FIG. 15B is a top down view of the exemplary first structure illustrated in FIG. 15A.

FIG. 16 is a cross sectional view after magnetically coupling the first structure illustrated in FIG. 14 and the second structure illustrated in FIG. 15, and thereafter performing a bonding process.

FIG. 17A is a cross sectional view of the 3D electronic structure shown in FIG. 16 after performing a re-polarization step.

FIG. 17B is a top down view of the exemplary 3D electronic structure shown in FIG. 17A with the first FEOL level removed for clarity.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

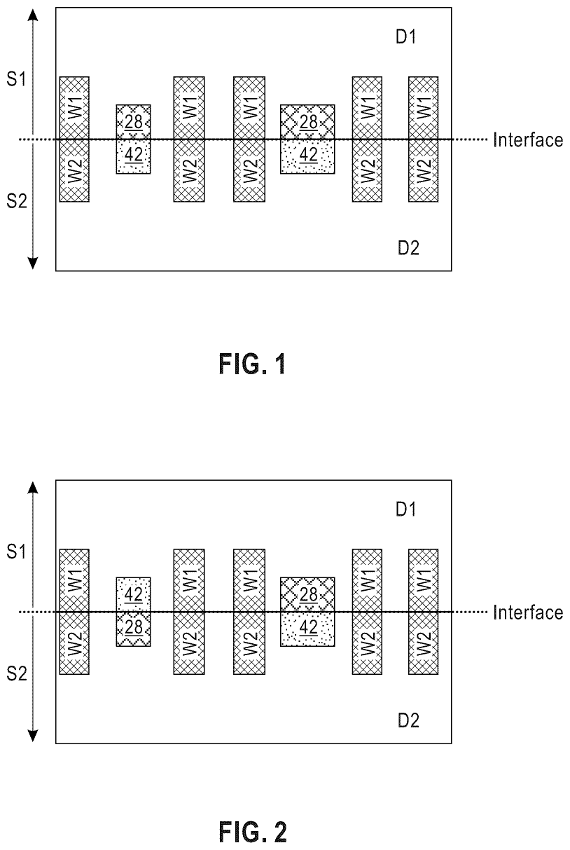

The present application provides 3D electronic structures (as illustrated, for example, in FIGS. 1-2) that include first substrate, S1, including at least one first ferromagnetic element 28 embedded in an outermost portion of the first substrate, S1, and second substrate, S2, including at least one second ferromagnetic element 42 embedded in an outermost portion of the second substrate, S2, in which the at least one first ferromagnetic element 28 is aligned to the least one second ferromagnetic element 42 at an interface that is present between the first substrate, S1, and the second substrate, S2. In such an embodiment, the least one first ferromagnetic element 28 and the at least one second ferromagnetic element 42 enable bump-less bonding at a tighter interconnect pitch.

In some embodiments, the 3D electronic structure (as illustrated in FIGS. 1 and 2) can further include first metal wiring, W1, present in the outermost portion of the first substrate, S1, and second metal wiring, W2, present in the outermost portion of the second substrate, S2, in which the first metal wiring, W1, and the second metal wiring, W2, are electrically connected at the interface. In such embodiments, the first metal wiring, W1, and the second metal wiring, W2, are interconnected without the presence of any solder bumps.

In some embodiments, the first substrate, S1, and the second substrate, S2, include a semiconductor die or chiplet.

In some embodiments, one of the first substrate, S1, or the second substrate, S2, includes a semiconductor die or chiplet, and the other of the first substrate, S1, or the second substrate, S2, includes an interposer structure.

In some embodiments, the first substrate, S1, is bonded to the second substrate, S2, at the interface, and the interface is a hybrid bonding interfacing including metal-to-metal bonds, and dielectric-to-dielectric bonds. This aspect of the present application provides a permanently bonded structure having the attributes of hybrid bonding.

In some embodiments of the present application, the at least one first ferromagnetic element 28 has a first polarity, and the at least one second ferromagnetic element 42 has a second polarity in which the second polarity is opposite the first polarity. This aspect of the present application enables alignment (via magnetic attraction) between the first and second ferromagnetic elements and facilities bump-less bonding at tighter interconnect pitch.

In some embodiments of the present application, the at least one first ferromagnetic element 28 and the at least one second ferromagnetic element 42 have a same polarity. This aspect of the present application enables formation of at least one ferromagnetic structure located at the interface in which a first portion of the at least one ferromagnetic structure is located in the first substrate, S1, and a second portion of the at least one ferromagnetic structure is located in the second substrate, S2.

In some embodiments (see, for example, FIG. 2), the outermost portion of the first substrate, S1, further includes a second ferromagnetic element 42 adjacent to the first ferromagnetic element 28, and the outermost portion of the second substrate, S2, further includes a first ferromagnetic element 28 adjacent to the second ferromagnetic element 42. In such embodiments, the second ferromagnetic element 42 of the first substrate, S1, is aligned to the first ferromagnetic element 28 of the second substrate, S2, at the interface. This aspect of the present application provides improved alignment within the 3D electronic structure.

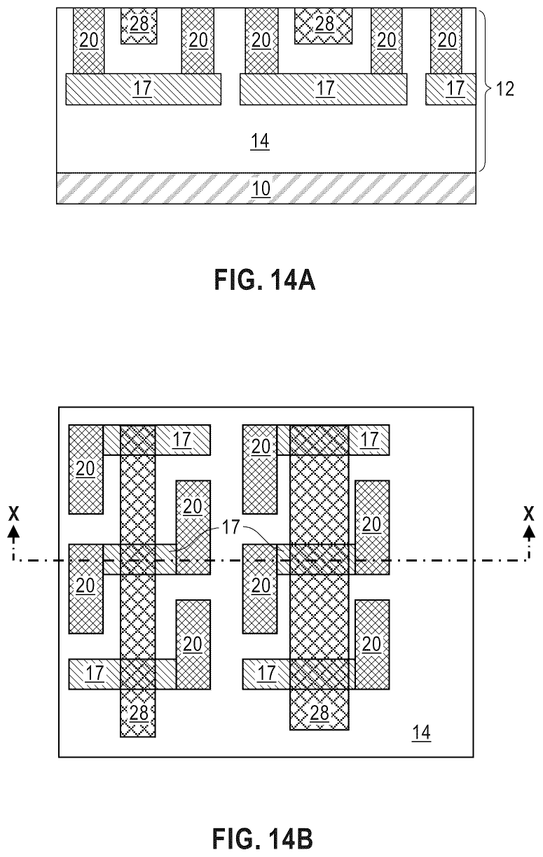

In some embodiments (see, for example, FIGS. 14A-17B), the at least one first ferromagnetic element 28 and the at least one second ferromagnetic element 42 have a same polarity and are bonded together at the interface to provide ferromagnetic core 45.

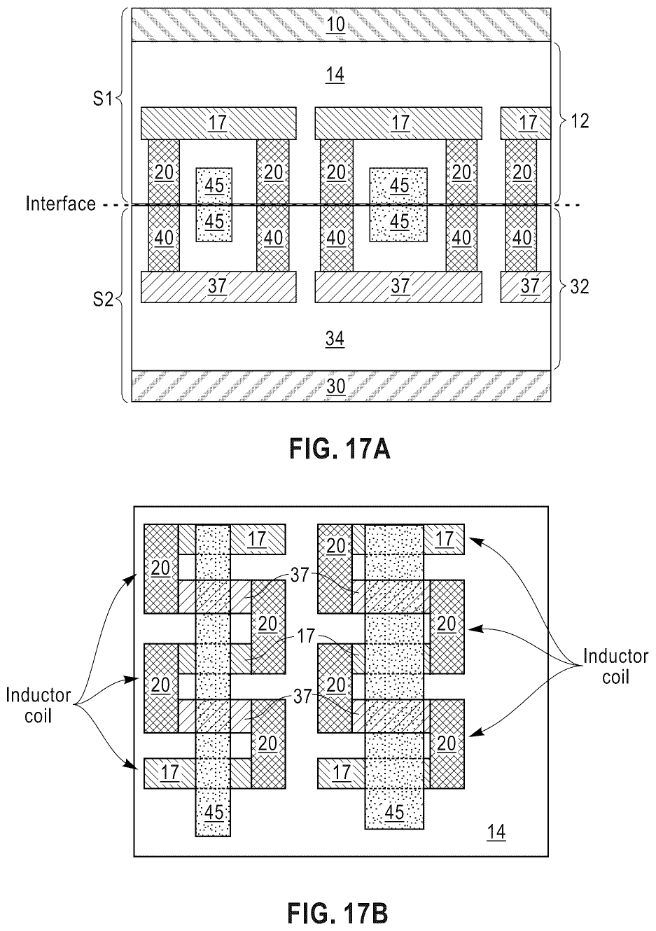

In such embodiments in which ferromagnetic core 45 is present (see, for example, FIGS. 17A-17B), the ferromagnetic core 45 is surrounded by an inductor coil, in which a first portion of the inductor coil is present in the first substrate, S1, and a second portion of the inductor coil is present in the second substrate, S2, and the first portion of the inductor coil is electrically connected to the second portion of the inductor coil at the interface. In this embodiment, the inductor coil surrounds the ferromagnetic core 45, and the ferromagnetic core 45 boosts the inductance of the inductor coil.

The present application, will now be described in further detail by referring to FIG. 1. Notably, FIG. 1 illustrates an exemplary 3D electronic structure in accordance with an embodiment of the present application. The exemplary 3D electronic structure illustrated in FIG. 1 includes first substrate, S1 and second substrate, S2. The first substrate, S1, and the second substrate, S2, include, but are not limited to, a semiconductor die, chiplet or interposer. In some embodiments of the present application, the first substrate, S1, is composed of same type of substrate as the second substrate, S1. For example, the first substrate, S1, can be a first semiconductor die or first chiplet and the second substate, S2, can be a second semiconductor die or second chiplet. In other embodiments of the present application, the first substrate, S1, is composed of different type of substrate as the second substrate, S1. For example, the first substrate, S1, can be a semiconductor die or chiplet and the second substate, S2, can be an interposer.

Throughout the present application, a semiconductor die is a small block of semiconductor material on which a given functional circuit is fabricated. Typically, integrated circuits are produced in large batches on a single wafer, and then the wafer is cut (or diced) into many pieces, each containing one copy of the circuit. Each of these pieces is called a semiconductor die. The semiconductor die can include an outermost portion that includes metal wiring region as defined below.

Throughout the present application, a chiplet is a tiny integrated circuit that contains a well-defined subset of functionality. A chiplet is designed to be combined with other chiplets on a carrier substate such as, for example, an interposer, in a single package to create a complex component such as a computer. Each chiplet in a computer processor provides only a portion of the processor's functionality. A set of chiplets can be implemented in a mix-and-match “Lego-like” assembly. The chiplet can include an outermost portion that includes metal wiring region as defined below.

Throughout the present application, an interposer is a structure that provides an electrical interface routing between one socket or connection to another. The purpose of an interposer is to spread a connection to a wider pitch or to reroute a connection to a different connection. An interposer can be made of either silicon or organic (printed circuit board-like) material. In one example, the interposer can include a semiconductor material core sandwiched between a first dielectric layer and a second dielectric layer. Metal wiring regions (including a through silicon via structure) can be present in the semiconductor material core, the first dielectric layer and the second dielectric layer.

For clarity, FIG. 1 illustrates an outermost portion of the first substrate, S1, and an outermost portion of the second substrate, S2. The outermost portion of the first substrate, S1, and the outermost portion of the second substrate, S2, can represent a portion of a frontside BEOL structure, a backside BEOL structure or an interposer. Notably, the outermost portion of the first substrate, S1, illustrated in FIG. 1 includes first metal wiring, W1, embedded in a first dielectric region, D1, and the outermost portion of the second substrate, S2, illustrated in FIG. 1 includes second metal wiring, W2, embedded in a second dielectric region, D2. The outermost portion of the first substrate, S1, illustrated in FIG. 1 also includes first ferromagnetic elements 28 embedded in a portion of the first dielectric region, D1. In embodiments of the present application, each ferromagnetic element is located in an outermost portion of the dielectric region of one substrate such that each ferromagnetic element in one substrate is close enough to another ferromagnetic element that is present in another substrate so as to have a strong enough attractive force across the bonding interface to achieve self-alignment. In the illustrated embodiments, the ferroelectric element of one substrate can be in direct physical contact with a ferromagnetic element of another substrate. Embodiments are also contemplated in which a gap can exist between the ferromagnetic element of one structure and the ferromagnetic element of another structure. The first ferromagnetic elements 28 have a first polarity (i.e., they have a first magnetic field that points in a first direction (i.e., north or south)). The outermost portion of the second substrate, S2, illustrated in FIG. 1 also includes second ferromagnetic elements 42 embedded in a portion of the second dielectric region, D2. The second ferromagnetic elements 42 have a second polarity. In some embodiments, the second polarity is opposite from the first polarity. In such embodiments, the second ferromagnetic elements 42 have a second magnetic field that points in a second direction (i.e., north or south) that is opposite from the first direction. As a consequence of having opposite polarities, the first ferromagnetic elements 28 and the second ferromagnetic elements 42 are attracted to each other. As such, self-alignment between the first ferromagnetic elements 28 and the second ferromagnetic elements 42 is achieved at the interface between the first substrate, S1, and the second substate S2. Also, and at the interface there is self-aligned contact between the first metal wiring, W1, and the second metal wiring, W2. It is noted that the number of first ferromagnetic elements 28 and the number of second ferromagnetic elements 42 can vary and is not limited to two as is illustrated in FIG. 1. For example, one first ferromagnetic element 28 or greater than two first ferromagnetic elements 28 can present in portion of the first substrate, S1, and one or greater than two second ferromagnetic elements 42 can present in the second substrate, S2. Although not a requirement, the number of first ferromagnetic elements 28 in the first substrate, S1, typically matches (i.e., is the same as) the number of second ferromagnetic elements 42 that is present in the second substrate, S2.

In some embodiments, and after performing a bonding process (to be described in greater detailed herein below), a re-polarization step can be performed to enable a same polarity between the aligned first ferromagnetic elements and the second ferroelectric elements.

In some embodiments, the first substrate, S1, and the second substrate, S2 illustrated in FIG. 1 are magnetically coupled together at the interface. In such embodiments, the first substrate, S1, and the second substrate, S2, are not permanently attached together. In other embodiments, a bonding process can be performed in which the first substrate, S1, and the second substrate, S2, are permanently bonded together at the interface. When a bonding process is performed, the interface between the first substrate, S1, and the second substrate, S2, can be referred to as a hybrid bond interface. In such cases, the hybrid bond interface includes a first hybrid bond between the first dielectric region, D1, and the second dielectric region, D2, a second hybrid bond between the first metal wiring, W1, and the second metal wiring, W2, and a third hybrid bond between the first ferromagnetic elements 28 and the second ferromagnetic elements 42. The third hybrid bond is optional and need not be present in embodiments in which a gap is located between the self-aligned first and second ferromagnetic elements. The first hybrid bond is a dielectric-to-dielectric bond. The first hybrid bond can be a covalent bond between the dielectrics that provide the first dielectric region, D1, and the second dielectric region, D2. In some embodiments, the first hybrid bond can also include dangling bonds in addition to the covalent bonds. Each of the second hybrid bond and the third hybrid bond is a metal-metal-bond. Notably, the second hybrid bond is a metal-to-metal bond between the first metal wiring, W1, and the second metal wiring, W2, and the third hybrid bond is a metal-to-metal bond between the first ferromagnetic elements 28 and the second ferromagnetic elements 42. It is noted that first metal wiring, W1, and the second metal wiring, W2, are self-aligned at the interface and that no solder bumps are used in providing the 3D electronic structure illustrated in FIG. 1.

Referring now to FIG. 2, there is illustrated exemplary 3D electronic structure in accordance with another embodiment of the present application. The exemplary 3D electronic structure illustrated in FIG. 2 includes first substrate, S1 and second substrate, S2, as defined above. For clarity, FIG. 2 illustrates an outermost portion of the first substrate, S1, and an outermost portion of the second substrate, S2. The outermost portion of the first substrate, S1, includes first metal wiring, W1, embedded in a first dielectric region, D1, and the outermost portion of the second substrate, S2, includes second metal wiring, W2 embedded in a second dielectric region, D2. The outermost portion of the first substrate, S1, and the outermost portion of the second substrate, S2, can represent a portion of a frontside BEOL structure, a backside BEOL structure or an interposer. The outermost portion of the first substrate, S1, and the outermost portion of the second substrate, S2, illustrated in FIG. 2 also include a first ferromagnetic element 28 and a second ferromagnetic element 42 embedded in a portion of the respective dielectric region. The first ferromagnetic element 28 has a first polarity, and the second ferromagnetic element 42 has a second polarity. In some embodiments, the second polarity is opposite the first polarity. In the illustrated embodiment shown in FIG. 2, the outermost portion of the first substrate, S1, and the outermost portion of the second substrate, S2 further includes at least one pair of oppositely polarized ferromagnetic elements present embedded in the respective dielectric region. In such an embodiment, the first ferromagnetic element 28 present in the first substrate, S1, and the second ferromagnetic element 42 present in the second substrate, S2, are attractive to each other, and the second ferromagnetic element 42 present in the first substrate, S1, and the first ferromagnetic element 28 present in the second substrate, S2, are attractive to each other. As such, self-alignment between the first ferromagnetic elements 28 and the second ferromagnetic elements 42 is achieved at the interface between the first substrate, S1, and the second substate S2. Also, and at the interface, there is self-aligned contact between the first metal wiring, W1, and the second metal wiring, W2. The exemplary 3D electronic structure illustrated in FIG. 2 may provide improved alignment compared to the 3D exemplary structure shown in FIG. 1 due to the presence of the least one pair of oppositely polarized ferromagnetic elements in the first substrate, S1, and the second substrate, S2. It is noted that first metal wiring, W1, and the second metal wiring, W2, are self-aligned at the interface and that no solder bumps are used in providing the 3D electronic structure illustrated in FIG. 2.

In some embodiments, and after performing a bonding process, a re-polarization step can be performed to enable a same polarity between the aligned first ferromagnetic elements and the second ferroelectric elements.

In some embodiments, the first substrate, S1, and the second substrate, S2 illustrated in FIG. 2 are magnetically coupled together at the interface. In such embodiments, the first substrate, S1, and the second substrate, S2 are not permanently attached together. In other embodiments, a bonding process can be performed in which the first substrate, S1, and the second substrate, S2, are permanently bonded together at the interface. When a bonding process is performed, the interface between the first substrate, S1, and the second substrate, S2, can be referred to as a hybrid bond interface. In such cases, the hybrid bond interface includes a first hybrid bond between the first dielectric region, D1, and the second dielectric region, D2, a second hybrid bond between the first metal wiring, W1, and the second metal wiring, W2, and a third hybrid bond between the first ferromagnetic elements 28 and the second ferromagnetic elements 42. The third hybrid bond is optional and is not present in instances in which a gap is located between the self-aligned first and second ferromagnetic elements. The first hybrid bond is a dielectric-to-dielectric bond. The first hybrid bond can be a covalent bond between the dielectrics that provide the first dielectric region, D1, and the second dielectric region, D2. In some embodiments, the first hybrid bond can also include dangling bonds in addition to the covalent bonds. Each of the second hybrid bond and the third hybrid bond is a metal-metal-bond. Notably, the second hybrid bond is a metal-to-metal bond between the first metal wiring, W1, and the second metal wiring, W2, and the third hybrid bond is a metal-to-metal bond between the first ferromagnetic elements 28 and the second ferromagnetic elements 42.

The first dielectric region, D1, and the second dielectric region, D2, illustrated in the exemplary 3D electronic structures illustrated in FIGS. 1-2 are composed one or more interlayer dielectric (ILD) layers. The one or more ILD layers of are composed of an ILD material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. All dielectric constants mentioned herein are measured in a vacuum unless otherwise stated. The first dielectric region, D1, can be compositionally the same as, or compositionally different from, the second dielectric region, D2.

In some embodiments, the outermost portion of the first dielectric region, D1, and/or the outermost portion the second dielectric region, D2, in which the ferromagnetic elements (i.e., first ferromagnetic elements 28 and the second ferromagnetic elements 42) are embedded is composed of a bonding dielectric material such as, for example, TEOS, SiO₂, SiCN, and/or SiCOH. The presence of a bonding dielectric material at the outermost portion of the first dielectric region, D1, and/or the outermost portion the second dielectric region, D2, provides increased bonding strength to the 3D electronic structure of the present application.

The first metal wiring, W1, and the second metal wiring, W2, illustrated in the exemplary 3D electronic structures of FIGS. 1-2 are composed of electrically conductive metal or an electrically conductive metal alloy. Exemplary electrically conductive metals include, but are not limited to, Cu, W, Al, Co, or Ru. An exemplary electrically conductive metal alloy is a Cu-Al alloy. The first metal wiring, W1, and the second metal wiring, W2, can be composed of a compositionally same, or compositionally different, electrically conductive material. The metal wiring that provides the first metal wiring, W1, can be composed of a compositionally same, or compositionally different electrically conductive material. Likewise, the metal wiring that provides the second metal wiring, W1, can be composed of a compositionally same, or compositionally different, electrically conductive material.

The first ferromagnetic elements 28 and the second ferromagnetic elements 42 illustrated in FIGS. 1-2 are composed of a ferromagnetic material. As used throughout the present application, the term “ferromagnetic material” denotes a material that exhibits a strong response to an external magnetic and that material retains its magnetization even after removing the external magnetic field. A ferromagnetic material exhibits the property of ferromagnetism which is a physical phenomenon in which magnetic polarization results from the application of an external magnetic field. Examples of ferromagnetic materials that can be used in providing the first ferromagnetic elements 28 and the second ferromagnetic element 42 include, but are not limited to, transition metals, transition metal alloys, rare earth metals, alloys of rare earth metals or any combination thereof. Exemplary transition metals that exhibit ferromagnetism include, but are not limited to, Co, Fe or Ni. Exemplary rare earth metals include, but are not limited to, Sc, Y and a lanthanide element of atomic number 57-such as, for example, La. Ge, Pr, Nd, Pm, Sm, Eu, Gd, Tb, Dy, Ho, Er, Tm, Yb and Lu. Ferromagnetism results from these materials having many unpaired electrons in their d-block (in the case of transition metals) or f-block (in the case of the rare-earth metals), a result of Hund′ rule or maximum multiplicity. The first ferromagnetic elements 28 can be composed of a compositionally same ferromagnetic material as, or compositionally different ferromagnetic material than, the second ferromagnetic element 42. The first ferromagnetic elements 28 and the second ferromagnetic elements 42 have saturated polarization. The first ferromagnetic elements 28 and the second ferromagnetic elements 42 can have opposite polarities (required for alignment of the first and second substrates) or they can have a same polarity (in such cases, a structure is provided including the first ferromagnetic elements 28 and the second ferromagnetic elements 42 having opposite polarities, and after bonding, a re-polarization step is used to provide self-aligned first and second ferromagnetic elements of the same polarity).

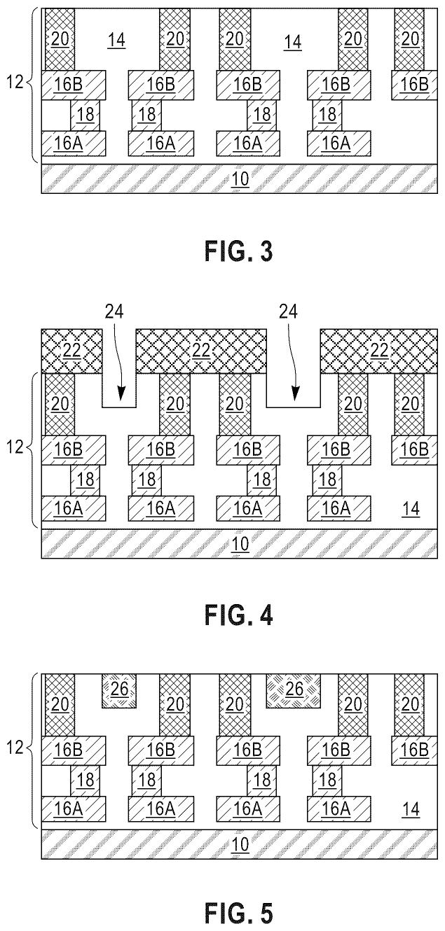

In a specific embodiment, of the present application, a 3D electronic structure is provided (such as can be formed from the processing steps illustrated in FIGS. 3-9 and FIGS. 10-13) that includes a first substrate including a first BEOL structure 12 located on a first FEOL level 10, in which the first BEOL structure 12 includes first metal wiring (including, for example, a first level of first metal lines 16A, a second level of first metal lines 16B, first interconnect vias 18, and first upper vias 20) and at least one first ferromagnetic element 28 located in an outermost portion of the first BEOL structure 12. The 3D electronic structure of this embodiment further includes a second substrate including a second BEOL structure 32 located on a second FEOL level 30, in which the second BEOL structure 32 includes second metal wiring (including, for example, a first level of second metal lines 36A, a second level of second metal lines 36B, second interconnect vias 38, and second upper vias 40) and at least one second ferromagnetic element 42 located in an outermost portion of the second BEOL structure 32. In accordance with the present application, the at least one first ferromagnetic element 28 is aligned to the at least one second ferromagnetic element 42 at an interface that is present between the first substrate and the second substrate and the first metal wiring is electrically connected to the second metal wiring at the interface. The metal wiring between the two substrates is self-aligned and is electrically connected without the need of using solder bumps.

In some embodiments of the present application, the at least one first ferromagnetic element 28 has a first polarity, and the at least one second ferromagnetic element 42 has a second polarity in which the second polarity is opposite the first polarity. This aspect of the present application enables formation of at least one ferromagnetic structure located at the interface in which a first portion of the at least one ferromagnetic structure is located in the first substrate, S1, and a second portion of the at least one ferromagnetic structure is located in the second substrate, S2.

In some embodiments of the present application, the at least one first ferromagnetic element 28 and the at least one second ferromagnetic element 42 have a same polarity. This aspect of the present application enables formation of at least one ferromagnetic structure located at the interface in which a first portion of the at least one ferromagnetic structure is located in the first substrate, S1, and a second portion of the at least one ferromagnetic structure is located in the second substrate, S2.

In some embodiments, the outermost portion of the first BEOL structure 12 further includes a second ferromagnetic element 42 adjacent to the first ferromagnetic element 28, and the outermost portion of the second BEOL structure 32 further incudes a first ferromagnetic element 28 adjacent to the second ferromagnetic element 42, and the second ferromagnetic element 42 of the first BEOL structure 12 is aligned to the first ferromagnetic element 28 of the second BEOL structure 32 at the interface. This aspect of the present application provides further alignment improvements within the 3D electronic structure.

In some embodiments, the first BEOL structure 12 is a frontside BEOL structure, and the second BEOL structure 32 is one of a backside BEOL structure or a frontside BEOL structure.

In some embodiments, the first BEOL structure 12 is a backside BEOL structure and the second BEOL structure 32 is one of a backside BEOL structure or a frontside BEOL structure.

In some embodiments, the first substrate is bonded to the second substrate at the interface, and the interface is a hybrid bond interface including metal-to-metal bonds and dielectric-to-dielectric bonds.

Referring now to FIGS. 3-9, there are illustrated various processing steps that can be employed in forming an exemplary 3D electronic structure of the present application similar to the one depicted in FIG. 1. Notably, FIG. 3 illustrates a first exemplary structure that can be used in the present application in providing an exemplary structure such as shown in FIG. 1. The first exemplary structure illustrated in FIG. 3 includes first BEOL structure 12 located on first FEOL level 10. The first FEOL level 10 includes one or more semiconductor devices, such as, for example, transistors, capacitors, resistors or any combination thereof. The one or more semiconductor devices present in the first FEOL level 10 can be present on a semiconductor substrate. When present, the semiconductor substrate can be included as one element of the first FEOL level 10. The semiconductor substrate can include at least a semiconductor device layer. The semiconductor device layer is an uppermost portion of the semiconductor substrate in which at least one semiconductor device such as, for example, a transistor, will be formed thereon. The semiconductor substrate can also include a semiconductor base layer and/or an etch stop layer. In one example, the semiconductor substrate can include from bottom to top, a semiconductor base layer, an etch stop layer and a semiconductor device layer. The semiconductor base layer of the semiconductor substrate is composed of a first semiconductor material, and the semiconductor device layer of the semiconductor substrate is composed of a second semiconductor material. As used throughout the present application, the term “semiconductor material” denotes a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the semiconductor device layer can be compositionally the same as, or compositionally different from, the first semiconductor material that provides the semiconductor base layer. In some embodiments of the present application, the etch stop layer of the semiconductor substrate can be composed of a dielectric material such as, for example, silicon dioxide and/or boron nitride. In other embodiments of the present application, the etch stop layer of the semiconductor substrate is composed of a third semiconductor material that is compositionally different from the first semiconductor material that provides the semiconductor base layer and the second semiconductor material that provides the semiconductor device layer. In one example, the semiconductor base layer is composed of silicon, the etch stop layer is composed of silicon dioxide, and the semiconductor device layer is composed of silicon. In another example, the semiconductor base layer is composed of silicon, the etch stop layer is composed of silicon germanium, and the semiconductor device layer is composed of silicon.

In one embodiment, the one or more semiconductor devices present in the first FEOL level 10 include at least one transistor. A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. The gate structure includes a gate dielectric and a gate electrode. In the present application, and when a transistor is present, the transistor can be a planar transistor, or a non-planar transistor including, but not limited to, a FinFET, a nanosheet transistor, a nanowire transistor, a fork sheet transistor, or a FET stack including at least one transistor stack above another transistor. The one or more semiconductor devices can be formed utilizing conventional semiconductor devices processing that is well known to those skilled in the art. For example, nanosheet transistors can be formed utilizing any well-known nanosheet transistor formation process.

The first FEOL level 10 can also include ILD layer which embeds at least a portion of the one or more semiconductor devices. The ILD layer includes an ILD material as previously described in the present application.

Although not illustrated in the drawings, a frontside contact level or a backside contact level including contact structures (e.g., source/drain contact structures) embedded in one or more ILD layers can be present between the first FEOL level 10 and the first BEOL structure 12. The one or more ILD layers are composed of an ILD material including those mentioned above. The contact structures are composed of at least a contact conductor material. The contact conductor material can include, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. The contact structures can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above. The frontside level or the backside level including the contact structures can be formed utilizing processing techniques that are well known to those skilled in the art such, as for example, deposition of the ILD layer and metallization.

The first BEOL structure 12 which is disposed on one side of the first FEOL level 10, includes a first interconnect dielectric region 14 having first metal wiring embedded therein. In some embodiments, the first BEOL structure 12 is a frontside BEOL structure in which the first metal wiring is typically configured as signal wires. In other embodiments, the first BEOL structure 12 is a backside BEOL structure in which the first metal wiring is typically configured for backside power delivery The first interconnect dielectric region 14 includes one or more interconnect dielectric material layers. The interconnect dielectric material layers of the first interconnect dielectric region 14 can be composed of at least one of the ILD materials mentioned above. In the illustrated embodiment, the first metal wiring includes a first level of first metal lines 16A, a second level of first metal lines 16B, first interconnect vias 18, and first upper vias 20. The first upper vias 20 extend from the second level of first metal lines 16B to a topmost surface of the first BEOL structure 12. The first metal wiring is composed of an electrically conductive metal or an electrically conductive metal alloy. The first BEOL structure 12 can be formed utilizing any well-known BEOL process including a damascene process or a subtractive metal etch process. The first BEOL structure 12 can represents the outermost portion of the first substrate, S1, illustrated in FIG. 1.

Although not shown, a different BEOL structure than the first BEOL structure 12 can be disposed on a second side of the first FEOL level 10 in which the second side is opposite the first side that includes first BEOL structure 12. When the first BEOL structure 12 is a frontside BEOL structure, the different BEOL structure is a backside BEOL structure. When the first BEOL structure 12 is a backside BEOL structure, the different BEOL structure can be a frontside BEOL structure. The different BEOL structure can include an interconnect dielectric region (composed of one or more ILD layers) having metal wiring embedded therein. The metal wiring can include metal lines, metal vias, metal line/metal via combinations or any combination thereof. The metal wiring is composed of an electrically conductive metal or electrically conductive metal alloy as mentioned above. The different BEOL structure than the first BEOL structure 12 can be formed utilizing any well-known BEOL process including a damascene process or a subtractive metal etch process.

Next, and as is illustrated in FIG. 4, openings 24 are formed into an upper portion of the first interconnect dielectric region 14 of the first BEOL structure 12. The openings 24 are formed by first forming a patterned mask 22 on a physically exposed surface of the first BEOL structure 12. The patterned mask 22 is composed of any well-known masking material or combination of well-known masking materials. For example, the patterned mask 22 can be composed solely of a photoresist material, or it can include a combination of a hard mask material (such as for example, silicon dioxide, silicon nitride and/or silicon nitride) and a photoresist material. In some embodiments in which the patterned mask 22 is composed solely of a photoresist material, the patterned mask 22 can be formed by deposition of the photoresist material, exposing the as-deposited photoresist material to a desired pattern of irradiation, followed by developing the photoresist material. In other embodiments, a hard mask material and a photoresist material is employed, the patterned mask 22 can be formed by deposition of the hard mask material, followed by lithographic patterning of the as-deposited hard mask material. Lithographic patterning includes forming a photoresist material on a layer/multilayered stack that needs to be patterned, exposing the as deposited photoresist material to a desired pattern of irradiation, developing the photoresist material and transferring the pattern from the developed photoresist material into the layer/multilayered stack that needs to be patterned, the transferring of the pattern can include one or more etching processes. The one or more etching processes can include dry etching and/or wet etching. Dry etching can include reactive ion etching (RIE), plasma etching or ion beam etching. Wet etching can include the use of a chemical etchant that is selective in removing physically exposed portions of the layer/multilayered stack that needs to be patterned. The photoresist material is removed after the pattern transfer process utilizing a material removal process that is selective in removing the photoresist material. In either embodiment, the patterned mask 22 includes a pattern of openings present therein. After forming the patterned mask 22, the pattern of openings present in the patterned mask 22 is transferred into the upper portion of the first interconnect dielectric region 14 by an etch such as, for example, RIE.

After transferring the pattern of openings present in the patterned mask 22 into the upper portion of the first interconnect dielectric region 14, the patterned mask 22 can be removed utilizing a material removal process that is selective in removing the patterned mask 22 from the first exemplary structure. In one example, an ashing step can be used to remove the patterned mask 22 from the first exemplary structure.

Next and after removing the patterned mask 22 from the first exemplary structure, a first ferromagnetic material containing structure 26 is formed into each of the openings 24 as is illustrated in FIG. 5. Each first ferromagnetic material containing structure 26 is formed into an upper portion of the first interconnect dielectric region 14. The number of first ferromagnetic material containing structures 26 that is formed into the upper portion of the first interconnect dielectric region 14 depends on the number of openings 24 that were previously formed into the upper portion of the first interconnect dielectric region 14. Typically, at least one, more typically, two or more first ferromagnetic material containing structures 26 are formed. Each first ferromagnetic material containing structure 26 is composed of a ferromagnetic material as defined above.

The first ferromagnetic material containing structure 26 can be formed by depositing a first ferromagnetic material layer on top of the first BEOL structure 12 and within each opening 24. The depositing of the ferromagnetic material layer can include chemical vapor deposition (CVD), plasma enhanced chemical vapor deposition (PECVD), atomic layer deposition (ALD), or sputtering. After depositing the first ferromagnetic material layer, a planarization process such as, for example, chemical mechanical planarization (CMP), can be used to remove the ferromagnetic material layer that is deposited on top of the first BEOL structure 12 and outside each of the openings 24. After planarization, the first ferromagnetic material layer remains in each of the openings 24. The remaining first ferromagnetic material layer that is within each of the openings 24 provides the first ferromagnetic material containing structure 26.

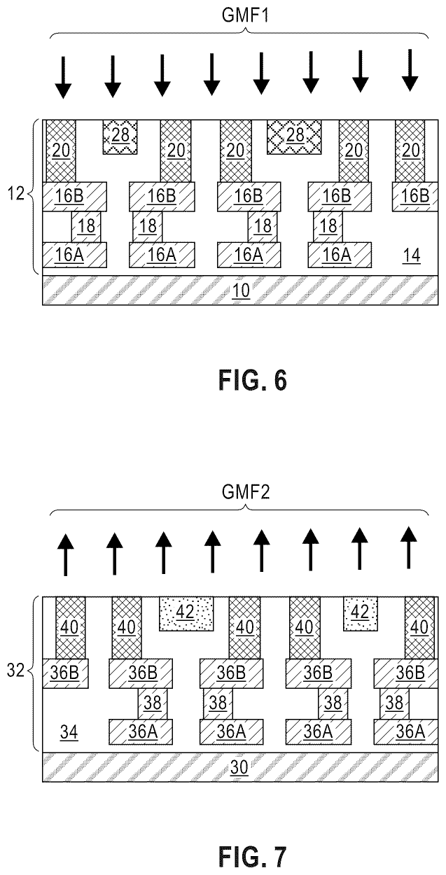

Next, and as is illustrated in FIG. 6, a first global external magnetic field (GMF1) is applied to the first exemplary structure to polarize each first ferromagnetic material containing structure 16 forming first ferromagnetic elements 28. The first ferromagnetic elements 28 have a first polarity. The first global external magnetic field is sufficient to cause saturated polarization of each first ferromagnetic material containing structure 26. The saturated polarized first ferromagnetic material containing structures 26 are referred to as the first ferromagnetic elements 28. The first BEOL structure 12 including the first ferromagnetic elements 28, and the first FEOL level 10 are components of a semiconductor die or chiplet and can be used as first substrate, S1, as is illustrated in FIG. 1.

Referring now to FIG. 7, there is illustrated a second exemplary structure that can be employed in the present application. The second exemplary structure shown in FIG. 7 can be formed utilizing processing steps similar to those shown in FIGS. 3-6 with the exception of applying a second global external magnetic field (GMF2) which is opposite in polarization to the first global external magnetic field (GMF1) mentioned above. The second exemplary structure illustrated in FIG. 7 includes a second BEOL structure 32 located on a second FEOL level 30, in which a second global external magnetic field (GMF2) is applied to polarize second ferromagnetic material containing structures (not shown) located in the second interconnect dielectric region 34 on the second FEOL level 30 forming second ferromagnetic elements 42. The second ferromagnetic elements 42 have a second polarity which at this point of the present application is opposite the first polarity. The second BEOL structure 32 including the second ferromagnetic elements 42, and the second FEOL level 30 are components of a semiconductor die or chiplet and can be used as second substrate, S2, as is illustrated in FIG. 1.

The second BEOL structure 32 contains second ferromagnetic elements 42 embedded in a second interconnect dielectric region 34. The second interconnect dielectric region 34 includes one or more ILD layers as mentioned above. In addition to including second ferromagnetic elements 42, the second BEOL structure 32 further includes second metal wiring. The second metal wiring includes a first level of second metal lines 36A, a second level of second metal lines 36B, second interconnect vias 38, and second upper vias 40. The second upper vias 40 extend from the second level of second metal lines to a topmost surface of the second BEOL structure 32. The second metal wiring is composed of an electrically conductive metal or an electrically conductive metal alloy.

At this point of the present application, each second ferromagnetic element 28 has a second polarity that is opposite the first polarity of the first ferromagnetic elements 28. Each second ferromagnetic element 42 is composed of a ferromagnetic material as mentioned above. The ferromagnetic material that provides each second ferromagnetic element 42 can be compositionally the same as, or compositionally different from, the ferromagnetic material that provides each first ferromagnetic element 28. The second global external magnetic field is sufficient to cause saturated polarization of second ferromagnetic material containing structure that were previously formed into the second BEOL structure 32. The saturated polarized second ferromagnetic material containing structures are referred to as the second ferromagnetic elements 42.

The second FEOL level 30 includes one or more semiconductor devices, such as, for example, transistors, capacitors, resistors or any combination thereof. The second FEOL level 30 includes elements as mentioned above for the first FEOL level. In embodiments, a frontside or backside contact level as defined above can be present between the second FEOL level 30 and the second BEOL structure 32.

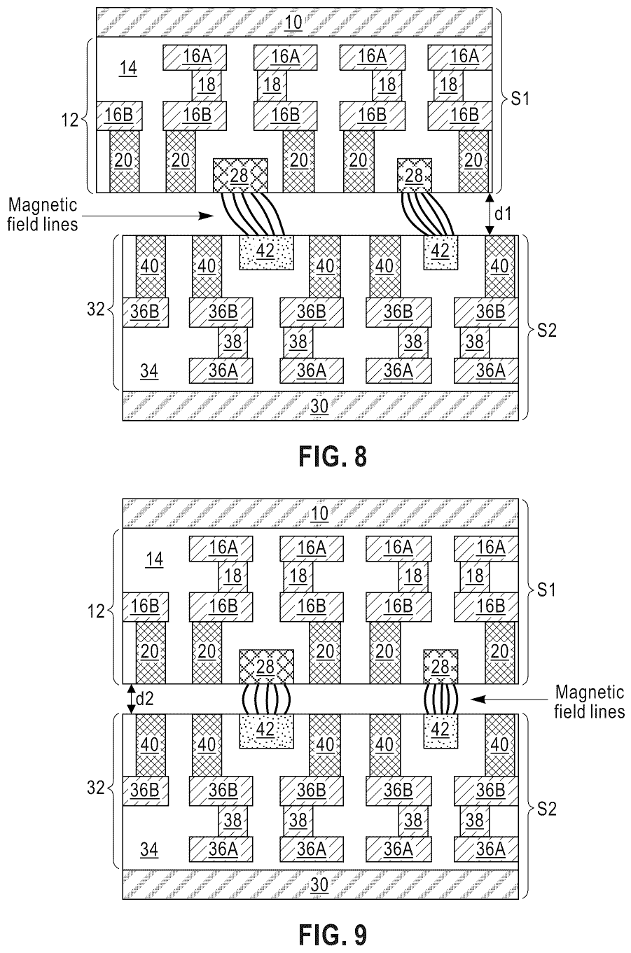

Referring now to FIG. 8, there is illustrated the first and second exemplary structures after performing a coarse alignment step at a first distance, d1, in which the first exemplary structure illustrated in FIG. 6 is flipped and positioned above the second exemplary structure shown in FIG. 7. Although the present application describes and illustrates flipping and positioning of the first exemplary structure over the second exemplary structure, the present application works when the second exemplary structure is flipped and positioned over the first exemplary structure. In the illustrated embodiment, the first exemplary structure illustrated in FIG. 6 is flipped 180° such the first ferromagnetic elements 28 are facing the second ferromagnetic elements 42. The flipping step can be performed manually or mechanically using, for example, a robot arm. The positioning step includes moving the first exemplary structure to a first distance, d1, from the second exemplary structure, such that the first ferromagnetic elements 28 and the second ferromagnetic elements 42 begin to first attract each other by means of magnetic field lines, as shown in FIG. 8. The coarse alignment step causes some alignment of the first ferromagnetic elements 28 and the second ferromagnetic elements 42.

Referring now to FIG. 9, there are illustrated the first and second exemplary structures after performing a fine alignment step at a second distance, d2, that is less than the first distance, d1, on the coarse-aligned first exemplary structure and second exemplary structure shown in FIG. 8. The alignment step includes moving the flipped first exemplary structure closer to the second exemplary structure such that attraction between the first ferromagnetic elements 28 and the second ferromagnetic elements 42 is stronger than the first attraction mentioned above. The fine alignment step causes nearly perfect (i.e., substantially) alignment of the first ferromagnetic elements 28 and the second ferromagnetic elements 42. Note that the fine alignment step also causes substantial alignment between the first upper vias 20 of the first BEOL structure 12 and the second upper vias 40 of the second BEOL structure 32. Although not illustrated, this fine alignment step causes the two exemplary structures to snap together forming a 3D electronic structure as depicted in FIG. 1. At this point of the present application, the first exemplary structure and the second exemplary structure are magnetically coupled, and not permanently bonded together.

In some embodiments, a bonding step can be performed to permanently bond the two exemplary structures that are magnetically coupled together. The bonding process employed is a hybrid bonding process. Hybrid bonding includes heating the two snapped together exemplary structures to form a hybrid bonding interface between the first exemplary structure and the second exemplary structure. Notably, a hybrid bonding interface is formed between the first BEOL structure 12 and the second BEOL structure 32. Specifically, the hybrid bonding interface is formed between the first interconnect dielectric region 14 and the second interconnect dielectric region 34, between the first upper vias 20 of the first BEOL structure 12 and the second upper vias 40 of the second BEOL structure 32, and between each magnetically coupled first ferromagnetic element 26 and second ferromagnetic element 42 pair. Heating can be performed from room temperature (i.e., 20°C.-25°C) typically up to 450° C.; temperatures greater than 450° C. can also be used in the present application. Heat is typically performed in an inert ambient such as, for example, He, Ar, Ne or mixtures thereof. After hybrid bonding, the temperature can be lowered back to room temperature. The hybrid bonding can also include an activation process including but not necessarily limited to, O₂/N₂ plasma activation followed by a de-ionized water rinsing. Such activation process creates surface dangling bonds through hydroxylation of dielectric surfaces. In such an embodiment, a dielectric-to-dielectric bond is formed between the first interconnect dielectric region 14 and the second interconnect dielectric region 34, a first metal-to-metal bond is formed between the first upper vias 20 of the first BEOL structure 12 and the second upper vias 40 of the second BEOL structure 32, and a second metal-to-metal bond is formed between each magnetically coupled first ferromagnetic element 26 and second ferromagnetic element 42 pair. The second metal-to-metal bond is optional and is not present in cases in which a gap is present between the self-aligned first and second ferromagnetic elements. At this point, a re-polarization process can be performed to cause a same polarization between the between the self-aligned first and second ferromagnetic elements.

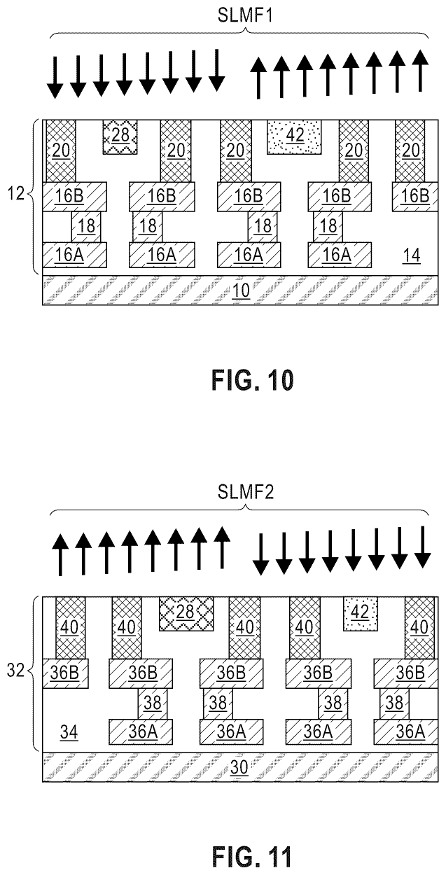

An exemplary 3D electronic structure illustrated, for example, in FIG. 2, can be prepared by first providing the first exemplary structure shown in FIG. 5. The exemplary structure shown in FIG. 5 can then be subjected to a first semi-local external magnetic field (SLMF1) to alternatively polarize the first ferromagnetic material containing structures 26 to provide a first pair of oppositely polarized ferromagnetic elements, i.e., first ferromagnetic element 28 and second ferromagnetic element 42, as shown in FIG. 10. The first semi-local external magnetic field is sufficient to cause saturated polarization of the first ferromagnetic material containing structures 26 that were previously formed into the first BEOL structure 12.

Referring now to FIG. 11, there is illustrated a second exemplary structure including second BEOL structure 32 located on a second FEOL level, 30 in which a second semi-local external magnetic field (SLMF2) is applied to alternatively polarize the second ferromagnetic material containing structures of the second BEOL structure 32 to provide a second pair of oppositely polarized ferromagnetic elements, i.e., first ferromagnetic element 28 and second ferromagnetic element 42. The second semi-local external magnetic field is sufficient to cause saturated polarization of the second ferromagnetic material containing structures that were previously formed into the second BEOL structure 32.

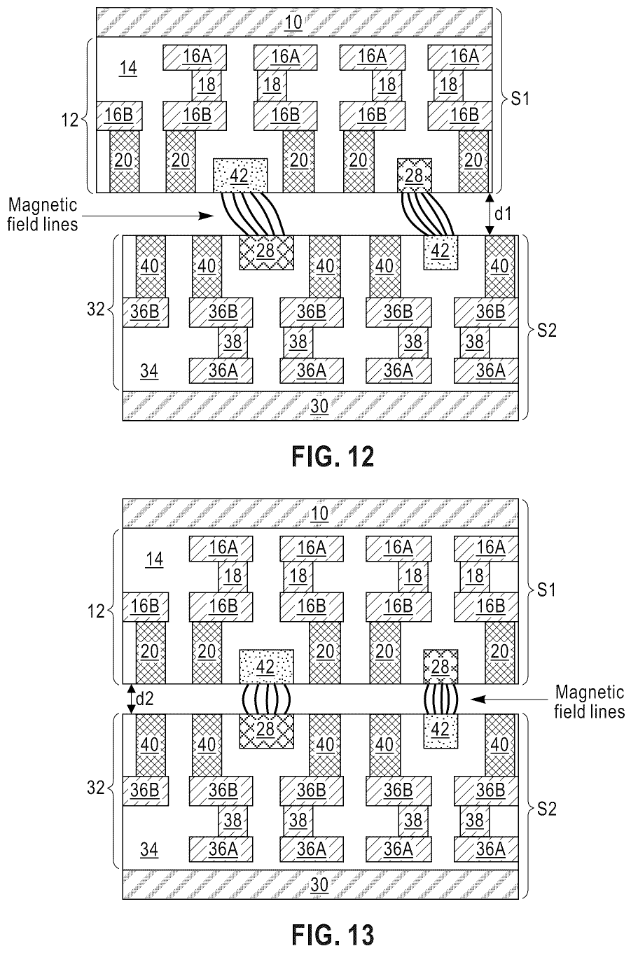

Referring now to FIG. 12, there is illustrated the first exemplary structure and second exemplary structure after performing a coarse alignment step at a first distance, d1, in which the first exemplary structure illustrated in FIG. 10 is flipped 180° and positioned above the second exemplary structure shown in FIG. 11. Although the present application describes and illustrates flipping and positioning of the first exemplary structure over the second exemplary structure, the present application works when the second exemplary structure is flipped and positioned over the first exemplary structure. In the illustrated embodiment, the first exemplary structure illustrated in FIG. 6 is flipped 180° such the first pair of oppositely polarized ferromagnetic elements, i.e., first ferromagnetic element 28 and second ferromagnetic element 42, of the first BEOL structure 12 are facing the pair of oppositely polarized ferromagnetic elements, i.e., first ferromagnetic element 28 and second ferromagnetic element 42, of the second BEOL structure 32. The flipping step can be performed manually or mechanically using, for example, a robot arm. The positioning step includes moving the first exemplary structure into a first distance, d1, from the second exemplary structure, such that the first ferromagnetic elements 28 and the second ferromagnetic elements 42 of the first and second pairs of oppositely polarized ferromagnetic elements begin to first attract each other by means of magnetic field lines, as shown in FIG. 12. The coarse alignment step causes some alignment of the first and second pairs of the oppositely polarized ferromagnetic elements.

Referring now to FIG. 13, there is illustrated the first exemplary structure and second exemplary structure after performing a fine alignment step at a second distance, d2, that is less than the first distance, d1, on the coarse-aligned first exemplary structure and second exemplary structure shown in FIG. 12. The alignment step includes moving the flipped first exemplary structure closer to the second exemplary structure such that attraction between the first and second pairs of the oppositely polarized ferromagnetic elements is stronger than the first attraction mentioned above. The fine alignment step causes nearly perfect (i.e., substantially) alignment of the first ferromagnetic elements 28 and the second ferromagnetic elements 42. Note that the fine alignment step also causes substantial alignment between the first upper vias 20 of the first BEOL structure 12 and the second upper vias 40 of the second BEOL structure 32. Although not illustrated, this fine alignment step causes the two exemplary structures to snap together forming a 3D electronic structure as depicted in FIG. 2. At this point of the present application, the first exemplary structure and the second exemplary structure are magnetically coupled (by attractive forces), and not permanently bonded together.

In some embodiments, a bonding step can be performed to permanently bond the two exemplary structures that are magnetically coupled together. The bonding process employed is a hybrid bonding process as described above. In this embodiment, a dielectric-to-dielectric bond is formed between the first interconnect dielectric region 14 and the second interconnect dielectric region 34, a first metal-to-metal bond is formed between the first upper vias 20 of the first BEOL structure 12 and the second upper vias 40 of the second BEOL structure 32, and a second metal-to-metal bond is formed between each magnetically coupled first and second pairs of the oppositely polarized ferromagnetic elements. The second metal-to-metal bond is optional and is not present in cases in which a gap is present between the self-aligned first and second ferromagnetic elements. At this point, a re-polarization process can be performed to cause a same polarization between the between the self-aligned first and second ferromagnetic elements.

In yet another embodiment of the present application, a 3D electronic structure as shown in FIGS. 17A-17B is provided that includes a first substrate including a first portion of an inductor coil, a second substrate including a second portion of the inductor coil, in which the second portion of the inductor coil is in direct electrical contact with the first portion of the inductor coil at an interface between the first substrate and the second substrate, and a ferromagnetic core 45 surrounded by the inductor coil. In this embodiment, the inductor coil represents metal wiring that is present in both the first substrate and the second substrate.

In some embodiments, the ferromagnetic core 45 includes a first ferromagnetic core element in the first substrate and a second ferromagnetic core element in the second substrate, wherein the first ferromagnetic core element and the second ferromagnetic core element are bonded together at the interface.

In some embodiments the first substrate is bonded to the second substrate at the interface, and the interface is a hybrid bonding interface including metal-to-metal bonds and dielectric-to-dielectric bonds.

Reference is now made to FIGS. 14A-17B which illustrates a process flow that can be used in forming a 3D electronic structure including an inductor coil surrounding the ferromagnetic core 45. In this embodiment, ferromagnetic elements of opposite polarization are used to magnetically couple a first substrate including a first portion of the inductor coil and a second substrate including a second portion of the inductor coil to form a 3D electronic structure including an inductor coil surrounding the ferromagnetic elements of opposite polarization, bonding to the first and second substrates together, and then performing a re-polarization to change the polarization of one of the ferromagnetic elements to match the polarization of the other ferromagnetic element. The repolarization provides ferromagnetic core 45 that is surrounded by an inductor coil. The presence of ferromagnetic core 45 boosts the inductance of the inductor coil. In the present application, the ferromagnetic core 45 is surrounded by an inductor coil in which a first portion of the inductor coil is present in first substrate, S1, and a second portion of the inductor coil is present in second substrate, S2; this aspect will become more apparent in the discussion below.

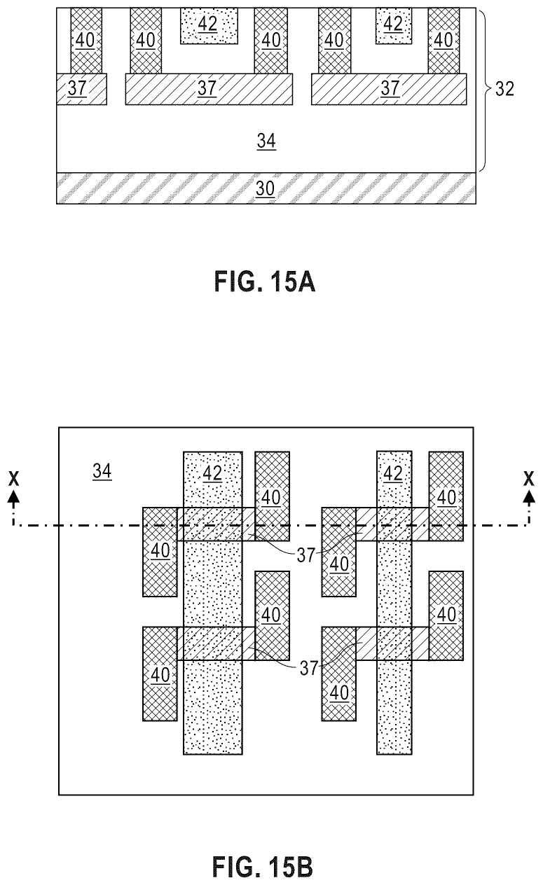

A first structure that can be employed in providing a 3D electronic structure including an inductor coil is illustrated in FIGS. 14A-14B, while a second structure that can be employed in providing the 3D electronic structure including the inductor coil is shown in FIGS. 15A-15B. It is noted that FIG. 14A is a cross sectional view through cut X-X shown in FIG. 14B, and that FIG. 15A is a cross sectional view through cut X-X shown in FIG. 15B. The first structure illustrated in FIGS. 141-14B represents a first substrate, S1, that includes a first portion of an inductor coil, while the second structure illustrated in FIGS. 15A-15B represents a second substrate, S2, that includes a second portion of the inductor coil. Notably, the first structure illustrated in FIGS. 14A-14B includes a first FEOL level 10 and a first BEOL structure 12. In this embodiment, the first BEOL structure 12 includes a pair of first upper vias 20 that extend upward from a first metal line 17. The pair of first upper vias 20 and the first metal line 17 are embedded in first interconnect dielectric region 14. The pair of first upper vias 20 and the first metal line 17 are composed of an electrically conductive metal or electrically conductive metal alloy as mentioned above. The first BEOL structure 12 can be a frontside BEOL structure or a backside BEOL structure. The first BEOL structure 12 also includes first ferromagnetic elements 28 having a first polarity. The first BEOL structure 12 minus the first ferromagnetic elements 28 can be formed utilizing any BEOL process that is well known in the art. The first ferromagnetic elements 28 can be formed utilizing the processing steps illustrated in FIGS. 4-6.

The second structure illustrated in FIGS. 15A-15B includes a second FEOL level 30 and a second BEOL structure 32. In this embodiment, the second BEOL structure 32 includes a pair of second upper vias 40 that extend upward from a second metal line 37. The pair of second upper vias 40 and the second metal line 37 are embedded in second interconnect dielectric region 44. The pair of second upper vias 40 and the second metal line 37 are composed of an electrically conductive metal or electrically conductive metal alloy as mentioned above. The second BEOL structure 32 can be a frontside BEOL structure or a backside BEOL structure. The second BEOL structure 32 also includes second ferromagnetic elements 42 having a second polarity that is opposite of the first polarity. The second BEOL structure 32 minus the second ferromagnetic elements 42 can be formed utilizing any BEOL process that is well known in the art. The second ferromagnetic elements 42 can be formed utilizing the processing steps illustrated in FIGS. 4-6.

It should be noted that while the present application describes and illustrates an embodiment in which both the first and second structures are components of a semiconductor die or chiplet, the present application contemplates an embodiment in which the pair of upper vias, metal line and ferromagnetic elements of one of the first structure or the second structure was formed in an interposer structure.

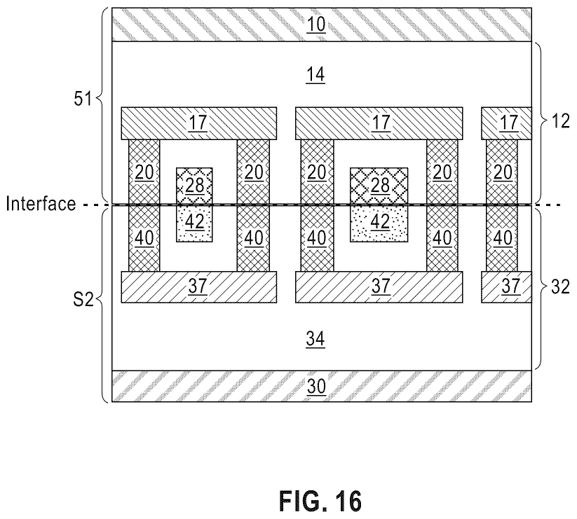

Referring now to FIG. 16, there is illustrated a 3D electronic structure after magnetically coupling of the first structure illustrated in FIG. 14A and the second structure illustrated in FIG. 15A, and thereafter performing a bonding process. The magnetic coupling includes the coarse alignment and fine alignment steps mentioned above with respect to FIGS. 8 and 9. Bonding can include a hybrid bonding process. The hybrid bonding process forms an hybrid bonding interface that includes a dielectric-to-dielectric bond between the first interconnect dielectric region 14 and the second interconnect dielectric region 44, a first metal-to-metal bond between the pair of first upper vias 20 and the pair of second upper vias 40, and second metal-to-metal bond between the first ferromagnetic elements 28 and the second ferromagnetic elements 42.

The 3D electronic structure illustrated in FIG. 16 includes at least one inductor coil (two of which are illustrated in the drawing). Each inductor coil includes the first metal line 17 electrically connected to the second metal line by the pair of first upper vias 20 and the pair of second upper vias 40 which are now permanently bonded together. Each inductor coil surrounds the first ferromagnetic element 28 and the second ferromagnetic element 42 which are also permanently bonded together.

Referring now to FIGS. 17A-17B, there are illustrated the 3D electronic structure shown in FIG. 16 after performing a re-polarization step. It is noted that FIG. 17A is a cross sectional view through cut X-X shown in FIG. 17B, and that in FIG. 17B the first FEOL level 10 is not shown for clarity. The re-polarization step includes the application of a global external magnetic field to change the polarization of one or both of the first ferromagnetic elements 28 and the second ferromagnetic elements 42 to provide a ferromagnetic core 45 in which the two bonded ferromagnetic elements have a same polarization. It is noted that the re-polarization step can be applied to the exemplary 3D electronic structures mentioned above (e.g., FIGS. 1 and 2). As mentioned above, a 3D electronic structure includes an inductor coil (composed of the pair of first upper vias 20 and the pair of second upper vias 40 which are now permanently bonded together) surrounding the ferromagnetic core 45. The ferromagnetic core 45 includes a first ferromagnetic core element (upper portion of ferromagnetic core 45 that is located above the interface) in the first substrate, S1, and a second ferromagnetic core element (lower portion of ferromagnetic core 45 that is located beneath the interface) in the second substrate, S2, in which the first ferromagnetic core element and the second ferromagnetic core element are bonded together at the interface.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A three-dimensional (3D) electronic structure comprising:
a first substrate comprising at least one first ferromagnetic element embedded in an outermost portion of the first substrate; and
a second substrate comprising at least one second ferromagnetic element embedded in an outermost portion of the second substrate, wherein the at least one first ferromagnetic element is aligned to the at least one second ferromagnetic element at an interface that is present between the first substrate and the second substrate.

2. The 3D electronic structure of claim 1, further comprising first metal wiring present in the outermost portion of the first substrate, and second metal wiring present in the outermost portion of the second substrate, wherein the first metal wiring and the second metal wiring are electrically connected at the interface.

3. The 3D electronic structure of claim 1, wherein the first substrate and the second substrate comprise a semiconductor die or chiplet.

4. The 3D electronic structure of claim 1, wherein one of the first substrate or the second substrate comprises a semiconductor die or chiplet, and the other of the first substrate or the second substrate is an interposer structure.

5. The 3D electronic structure of claim 1, wherein the first substrate is bonded to the second substrate at the interface, and the interface is a hybrid bonding interface comprising metal-to-metal bonds and dielectric-to-dielectric bonds.

6. The 3D electronic structure of claim 1, wherein the at least one first ferromagnetic element has a first polarity, and the at least one second ferromagnetic element has a second polarity that is opposite the first polarity.

7. The 3D electronic structure of claim 1, wherein the at least one first ferromagnetic element and the at least one second ferromagnetic element have a same polarity.

8. The 3D electronic structure of claim 1, wherein the outermost portion of the first substrate further comprises a second ferromagnetic element adjacent to the first ferromagnetic element, and the outermost portion of the second substrate further comprises a first ferromagnetic element adjacent to the second ferromagnetic element, and wherein the second ferromagnetic element of the first substrate is aligned to the first ferromagnetic element of the second substrate at the interface.

9. The 3D electronic structure of claim 1, wherein the at least one first ferromagnetic element and the at least one second ferromagnetic element have a same polarity and are bonded together at the interface to provide a ferromagnetic core.

10. The 3D electronic structure of claim 9, wherein the ferromagnetic core is surrounded by an inductor coil, wherein a first portion of the inductor coil is present in the first substrate and a second portion of the inductor coil is present in the second substrate, and the first portion of the inductor coil is electrically connected to the second portion of the inductor coil at the interface.

11. A three-dimensional (3D) electronic structure comprising:
a first substrate comprising a first back-end-of-the line (BEOL) structure located on a first front-end-of-the-line (FEOL) level, wherein the first BEOL structure comprises first metal wiring and at least one first ferromagnetic element located in an outermost portion of the first BEOL structure; and
a second substrate comprising a second BEOL structure located on a second FEOL level, wherein the second BEOL structure comprises second metal wiring and at least one second ferromagnetic element located in an outermost portion of the second BEOL structure, wherein the at least one first ferromagnetic element is aligned to the at least one second ferromagnetic element at an interface that is present between the first substrate and the second substrate and wherein the first metal wiring is electrically connected to the second metal wiring at the interface.

12. The 3D electronic structure of claim 11, wherein the at least one first ferromagnetic element has a first polarity, and the at least one second ferromagnetic element has a second polarity that is opposite the first polarity.

13. The 3D electronic structure of claim 11, wherein the at least one first ferromagnetic element and the at least one second ferromagnetic element have a same polarity.

14. The 3D electronic structure of claim 11, wherein the outermost portion of the first BEOL structure further comprises a second ferromagnetic element adjacent to the first ferromagnetic element, and the outermost portion of the second BEOL structure further comprises a first ferromagnetic element adjacent to the second ferromagnetic element, and wherein the second ferromagnetic element of the first BEOL is aligned to the first ferromagnetic element of the second BEOL structure at the interface.

15. The 3D electronic structure of claim 11, wherein the first BEOL structure is a frontside BEOL structure, and the second BEOL structure is one of a backside BEOL structure or a frontside BEOL structure.

16. The 3D electronic structure of claim 11, wherein the first BEOL structure is a backside BEOL structure and the second BEOL structure is one of a backside BEOL structure or a frontside BEOL structure.

17. The 3D electronic structure of claim 11, wherein the first substrate is bonded to the second substrate at the interface, and the interface is a hybrid bonding interface comprising metal-to-metal bonds and dielectric-to-dielectric bonds.

18. A three-dimensional (3D) electronic structure comprising:
a first substrate comprising a first portion of an inductor coil;
a second substrate comprising a second portion of the inductor coil, wherein the second portion of the inductor coil is in direct electrical contact with the first portion of the inductor coil at an interface between the first substrate and the second substrate; and
a ferromagnetic core surrounded by the inductor coil.

19. The 3D electronic structure of claim 18, wherein the ferromagnetic core comprises a first ferromagnetic core element in the first substrate and a second ferromagnetic core element in the second substrate, wherein the first ferromagnetic core element and the second ferromagnetic core element are aligned at the interface.

20. The 3D electronic structure of claim 18, wherein the first substrate is bonded to the second substrate at the interface, and the interface is a hybrid bonding interface comprising metal-to-metal bonds and dielectric-to-dielectric bonds.
